(19) United States
(12) Patent Application Publication
(10) Pub. No.: US 2025/0089433 A1
(43) Pub. Date: Mar. 13, 2025

(54) FLEXIBLE PEROVSKITE SOLAR CELL USING CONDUCTIVE GRID

(71) Applicant: Verde Technologies Incorporated, Burlington, VT (US)

(72) Inventors: Richards Galt Miller, Duxbury, VT (US); Randall Lewis Headrick, Burlington, VT (US); Vivek Babu, Essex Junction, VT (US)

(73) Assignee: Verde Technologies Incorporated, Burlington, VT (US)

(21) Appl. No.: 18/829,401

(22) Filed: Sep. 10, 2024

Related U.S. Application Data
(60) Provisional application No. 63/537,571, filed on Sep. 11, 2023.

(51) Int. Cl. H10K 30/81; H10K 30/40; H10K 30/85; H10K 30/86; H10K 77/10; H10K 85/10; H10K 85/20

(52) U.S. Cl. CPC H10K 30/81; H10K 30/40; H10K 30/86; H10K 85/111; H10K 85/211; H10K 30/85; H10K 77/111

(57) ABSTRACT

Techniques for solar cell realization are disclosed. A metallic foil substrate is obtained. The metallic foil substrate is flexible and rollable. A transport layer is deposited on the metallic foil substrate. The transport layer enables current conduction to the metallic foil substrate. A perovskite layer is added on the transport layer. The perovskite layer generates an electric current based on light energy impingement. An additional transport layer is provided on the perovskite layer. The additional transport layer complements the transport layer. The additional transport layer is isolated with a conductive layer. The conductive layer enables light transmission. A grid is connected on the conductive layer. The grid conducts electric current and enables light energy to reach the perovskite layer. The grid and the metallic foil substrate form contacts for photovoltaic operation.

### RELATED APPLICATIONS

This application claims the benefit of U.S. provisional patent application “Flexible Perovskite Solar Cell Using Conductive Grid” Ser. No. 63/537,571, filed Sep. 11, 2023.

The foregoing application is hereby incorporated by reference in its entirety.

### FIELD OF ART

This application relates generally to solar cell realization and more particularly to a flexible perovskite solar cell using a conductive grid.

### BACKGROUND

New technologies for energy generation are continuously being invented, developed, and improved. The new technologies are increasingly of interest not only in regions of the world where energy sources are inadequate or have been previously nonexistent, but also in regions where energy sources and their supporting infrastructures have long been in place. In the former regions, the remoteness of some areas and the cost of harnessing the energy sources can pose significant challenges. In the latter regions, concerns run high with respect to the environmental and climate damage that has resulted from burning fossil fuels, and the challenges of radioactive waste generated by nuclear-powered plants. Other concerns are being raised for energy sources, such as hydropower, that have traditionally been declared environmentally friendly. Dams and other structures have significantly changed water flows, resulting in declines in fish and other aquatic life species, riverbank erosion or other damage, and even earthquakes. Further, the lakes formed behind the dams have flooded lands where indigenous peoples built settlements and designated sacred sites. Another energy source that was originally declared to be “eco-friendly” was the burning of biomass. However, the burning of biomass is now recognized to produce pollutants and particles that are identified as harmful to animals and plants alike. “Old” energy generation technologies are also being reintroduced. These latter technologies, such as wind and tidal technologies, are creating increasing interest due to their renewable features. As long as the wind blows or tides ebb and flow, energy such as electrical energy can be generated by converting these natural phenomena.

Renewable energy sources, such as solar, wind, tidal, and geothermal sources, are becoming particularly popular because of their “earth friendly” credentials. These sources convert one energy form into another energy form such as electrical energy. The principal challenge of these and other renewable energy sources is that the sources are not necessarily available continuously. Solar energy can only be converted when the sun is shining. Similarly, wind energy can only be converted when the wind is blowing. Further, not all renewable energy sources are universally available. Conversion of geothermal energy to electricity is most effective in regions where high geothermal temperatures are accessible closest to the surface of the earth. Similarly, conversion of wave action to electricity operates best near the ocean or large bodies of water. As a result, the choice of renewable energy source is dependent on what renewable sources are readily available.

### SUMMARY

Alternatives to conventional energy generation sources are attracting great attention locally, regionally, nationally, and globally. The alternative sources are based on renewable energy from solar, wind, wave action, tidal, and geothermal sources, among others. The primary reason for the increased interest in renewable energy sources is concern for the environment. The burning of fossil fuels to generate electricity, for transportation, and so on has been shown to have resulted in grave environmental consequences including climate change. Further, the demand for electricity continues to expand. Not only are more energy users gaining access to sources of electricity, the demand by existing users for electricity is increasing. The increase in demand is being caused by the significantly increased interest in electric vehicles (EVs) and by changing requirements for domestic and commercial energy consumption. The domestic and commercial energy consumption results from heating, ventilation, and air conditioning (HVAC); and cooking; among other uses. Some city governments are requiring home and building owners to replace existing HVAC systems that consume fossil fuels with more energy efficient systems that operate using electricity. Further, the burning of natural gas, propane, butane, and so on for cooking is being discouraged or outright banned due to the production of indoor pollutants. These mandated changes are dramatically increasing electricity demands, thereby placing strains on electricity generation facilities and distribution infrastructures. One solution to the increase in electricity demands is to produce cost effective, stable, and readily manufactured solar cells.

Disclosed techniques include solar cell realization based on a flexible perovskite solar cell using a conductive grid. The perovskite solar cell is based on depositing layers of various materials onto a metallic foil substrate. The layers, which can be formed using a variety of fabrication techniques such as sputtering, spin coating, slot-coating, and so on, form a layering “stack-up”. The layers are used in conjunction with a perovskite layer to form a perovskite solar cell. The metallic foil substrate is foldable and rollable. As a result, the disclosed perovskite solar cell can be rolled during manufacture. The result of rolling the perovskite solar cell is a simplification of the manufacturing process. Further, the perovskite solar cells can be produced in various sizes, configurations including parallel and series configurations, and so on. The solar cells can be produced with uniform or various sizes, output voltages and currents, and so on. The flexible and rollable perovskite cells can be unrolled for use, rerolled for transport to another location, etc.

A metallic foil substrate is obtained. The metallic foil substrate is flexible and rollable. A transport layer is deposited on the metallic foil substrate. The transport layer enables current conduction to the metallic foil substrate. A perovskite layer is added on the transport layer. The perovskite layer generates an electric current based on light energy impingement. An additional transport layer is provided on the perovskite layer. The additional transport layer complements the transport layer. The additional transport layer is isolated with a conductive layer. The conductive layer enables light transmission. A grid is connected on the conductive layer. The grid conducts electric current, enables light energy to reach the perovskite layer, and, along with the metallic foil substrate, forms contacts for photovoltaic operation.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a flexible perovskite solar cell using a conductive grid.

FIG. 2 is a flow diagram for stabilizing a flexible perovskite solar cell using a conductive grid.

FIG. 3 is an infographic for NIP layering.

FIG. 4 is an infographic for layering PIN materials in a flexible perovskite solar cell using a conductive grid.

FIG. 5 is an infographic for a full stack-up of a flexible perovskite solar cell using a conductive grid.

FIG. 6 illustrates graphs of flexible perovskite solar cell performance.

FIG. 7 is a system diagram for a flexible perovskite solar cell using a conductive grid.

### DETAILED DESCRIPTION

Solar cells, and solar arrays formed from solar cells, are being deployed to provide primary, supplemental, and backup power to electrical energy grids worldwide. The solar cells and arrays tend to be heavy, rigid affairs that are securely mounted. These fixed installations typically remain in place for the useful lifespan of the solar cells, which can range from 25 to 30 years. Solar cells are particularly useful in regions such as equatorial ones where long days and clear skies provide significant amounts of solar energy consistently and year-round. Regions farther north or farther south can also benefit from energy produced by solar cells and arrays. However, the amount of energy produced by these northern and southern installations can vary greatly from season to season. Further, regions with numerous overcast days can still benefit from the use of solar cells and solar arrays, but the amount of electrical energy generated by the cells and arrays is directly, and at times significantly, reduced as a result of the decreased amount of solar energy available for conversion.

An emerging solar cell technology in the area of solar panels is based on perovskite compounds. A perovskite layer can be fabricated between transport layers, conducting layers, and so on to produce perovskite solar cells or PSCs. The benefits of perovskite solar cells include favorable parameters such as excellent light absorption, charge-carrier mobilities, and charge-carrier lifetimes. In addition, PSCs, unlike silicon solar cells (SSCs) based on high purity silicon (Si), are able to function even in the presence of some impurities. Further, the production of PSCs can be less precisely oriented than the production of SSIs, making PSCs attractive for mass production to meet expanding solar energy demands. However, while silicon solar cells can generate electrical energy from solar energy at an efficiency of roughly 90% for a period of 25 to 30 years, the useful life of perovskite solar cells tends to be much shorter. Current PSC technology has advanced to extend the useful lifespan of the cells for up to a few years. Such PSCs can be used for applications that require shorter cell lifespans, but the shorter lifespan does not meet the longevity of the SSC.

The perovskite solar cell is based on a metallic foil substrate. The metallic foil substrate can comprise aluminum, nickel, chromium, and other foils. In embodiments, the metallic foil comprises one or more of a group consisting of gold, silver, copper, aluminum, nickel, titanium, stainless steel, Molybdenum, and a Molybdenum alloy. The metal foil substrate can include a backing, such as a plastic backing, to improve mechanical stability of the solar cell. Transport layers and a perovskite layer can be formed on the metallic foil substrate. The transport layers, which include a hole transport layer and an electron transport layer, capture and transport holes and electrons, respectively, that are generated by the perovskite layer when light impinges on the perovskite layer. Further layers, including a conductive layer and a grid layer, enable connection to the perovskite solar cell. The grid layer and metallic foil substrate enable connection to the perovskite solar cell. The grid and the metallic foil substrate can act as terminals of contact to the solar cell. By making connections to the grid and the foil substrate, a voltage or a current generated by the perovskite solar cell can be accessed. The perovskite solar cell can be connected in parallel, in series, and so on, with other solar cells to achieve a desired voltage or current.

A metallic foil substrate is obtained. The metallic foil substrate is flexible and rollable. A transport layer is deposited on the metallic foil substrate. The transport layer enables current conduction to the metallic foil substrate. A perovskite layer is added on the transport layer. The perovskite layer generates an electric current based on light energy impingement. An additional transport layer is provided on the perovskite layer. The additional transport layer complements the transport layer. The additional transport layer is isolated with a conductive layer. The conductive layer enables light transmission. A grid is connected on the conductive layer. The grid conducts electric current, the grid enables light energy to reach the perovskite layer, and the grid, along with the metallic foil substrate, forms contacts for photovoltaic operation.

Disclosed techniques include a flexible perovskite solar cell using a conductive grid. The PSC with a conductive grid is highly stable and lightweight, and can be produced in a variety of sizes. The flexible perovskite solar cell is produced in rolls and with less stringent manufacturing tolerances than are required for production of SSCs. Further, the PSCs can be unrolled for deployment and can be rerolled for later use. The flexible and rollable PSCs are accomplished by fabricating the PSCs on a flexible and rollable metallic foil substrate. The production of additional layers in the PSC “stack-up” can be accomplished using techniques that include sputtering, spin coating, chemical vapor deposition, and so on. The PSC stack-up can include layers produced using screen printing, further simplifying their production. The use of a transparent conductive oxide (TCO) and conducting grid at the top of the stack-up can eliminate the need for the rigid glass top surface common to SSCs.

A metallic foil substrate is obtained, where the metallic foil substrate can comprise aluminum, nickel, chromium, and so on. The metallic foil substrate can include a flexible backing such as a plastic backing. The metallic foil substrate can be mounted on, can be adsorbed onto, can be deposited on, etc., the flexible backing. The metallic foil substrate is flexible and rollable. A transport layer is added on the metallic foil substrate. The transport layer can transport holes or electrons generated by a perovskite layer. The transport layer enables current conduction to the metallic foil substrate. A perovskite layer is added on the transport layer. The perovskite layer can be based on an ABX₃ material, where A can comprise a large metal cation, B can comprise a smaller metal cation, and X₃ can comprise an anion. The perovskite layer generates an electric current based on light energy impingement. An additional transport layer is provided on the perovskite layer, where the additional transport layer complements the transport layer. The transport layer transports either positive charge carriers (holes) or negative charge carriers (electrons), while the additional transport layer transports either electrons or holes (e.g., the complement of the transport layer). The additional transport layer can be isolated by a conductive layer. The conductive layer enables light transmission through to lower layers such as the perovskite layer. A grid is connected on the conductive layer. The grid can include parallel lines, a pattern, and so on that enables light energy to pass through. The grid conducts electric current, and the grid enables light energy to reach the perovskite layer. The grid and the metallic foil substrate form contacts for photovoltaic operation.

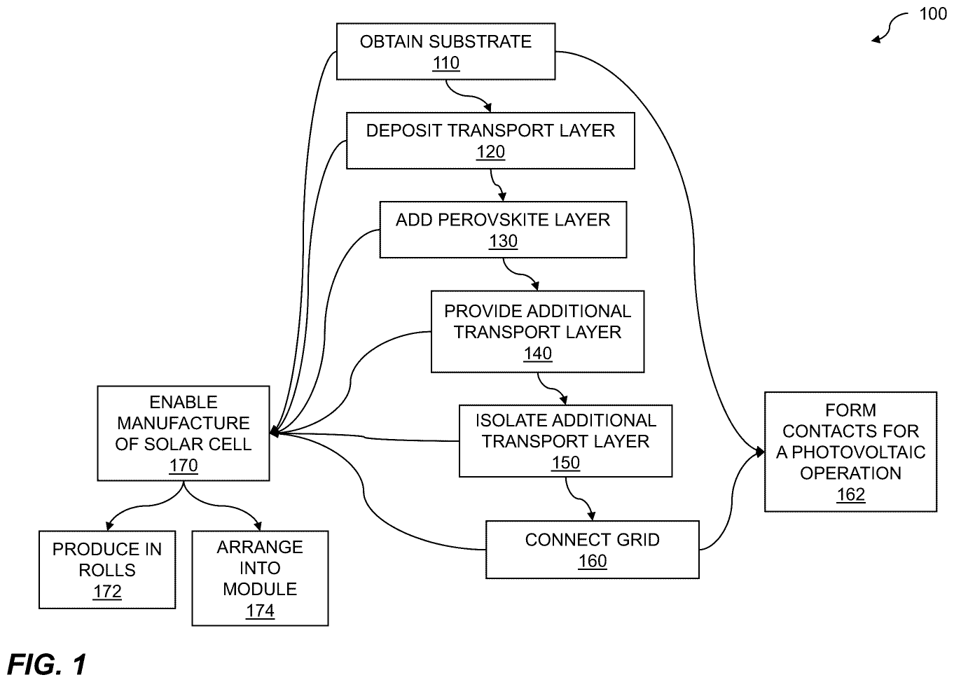

FIG. 1 is a flow diagram for a flexible perovskite solar cell using a conductive grid. Photovoltaic solar cells are widely used to produce electricity from sunlight. The cells can range in size and can include small, portable cells that can be used to charge devices such as personal electronic devices while traveling, camping, or enduring one of the many scheduled and unscheduled power outages. Photovoltaic cells also provide an electrical “lifeline” to people who live in remote areas or are in other locations where power such as electrical power is sporadic or generally unavailable. Perovskite solar cells can be produced on rolls, which reduces the complexity of manufacturing the solar cells and can simplify the transporting and deploying of the solar cells. The flexible perovskite solar cells can be rolled up for transport and unrolled when used. Further, the production of the perovskite solar cells can be accomplished using less complex manufacturing techniques such as thin film deposition, printing, and so on. The perovskite solar cells can be produced in both NIP (n-type/intrinsic/p-type) and PIN (p-type/intrinsic/n-type) configurations. The difference between these configurations can depend on placement of a transport layer and an additional transport layer. A transport layer can transport electrical charges such as positive charges (holes) and negative charges (electrons). The two configurations differ relative to the placement of a hole transport layer (HTL) and an electron transport layer (ETL) relative to the perovskite layer.

The flow 100 includes obtaining a metallic foil substrate 110, wherein the metallic foil substrate is flexible and rollable. The metallic foil substrate can include a standalone substrate, a backed substrate, and so on. The backed substrate can include a metallic foil substrate with a plastic backing or other flexible and rollable backing. The metallic foil substrate can be based on a variety of metals. The metals can include silver (Ag), gold (Au), or platinum (Pt), which are excellent conductors. However, the cost of each of these metals can be prohibitive. In addition, silver can cause long term reliability and stability challenges because of its propensity to oxidize. Other metals that can be used for the metallic foil substrate can include aluminum (Al), chromium (Cr), copper (Cu), iron (Fe) and some alloys of steel, nickel (Ni), and so on. The metal foil that is obtained can be sufficiently thin to be relatively lightweight, flexible, and rollable. In embodiments, the metallic foil comprises gold (Au), silver (Ag), copper (Cu), aluminum (Al), nickel (Ni), titanium (Ti), stainless steel, Molybdenum (Mo), or a Molybdenum alloy.

The flow 100 includes depositing a transport layer 120 on the metallic foil substrate. The transport layer that is deposited enables current conduction to the metallic foil substrate. The transport layer can be deposited on the metallic foil using one or more of various deposition techniques. In embodiments, the deposition can be accomplished using a sputtering technique. A transport layer can transport electrical charges, where the electrical charges can be generated by a layer such as a perovskite layer (discussed below). A transport layer can transport positive electrical charges (holes) or negative electrical charges (electrons). In embodiments, the transport layer can include a hole transport layer (HTL). The HTL can be fabricated based on depositing any of a variety of materials. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport. Other suitable HTL layer materials can include Copper(I) Oxide (Cu₂O), Copper(I) Thiocyanate (CuSCN), Copper Antimony Sulfide (CuSbS₂), Poly(3-hexylthiophene) (P3HT), Poly(3,4-ethylenedioxythiophene) polystyrene sulfonate (PEDOT), Spiro-OMeTAD, Copper(I) Iodide (CuI), Copper(I) Oxide (Cu₂O), Vanadium (V) Oxide (V₂O₅), Copper Bismuth Thiostannate (CBTS), and Copper Tin Sulfide (CFTS).

In embodiments, a thin conducting layer can be inserted between the metallic foil substrate and the transport layer. The transport layer can include a hole transport layer or an electron transport layer. The transport layer to which the thin conduction layer can be inserted can depend on the structure of a perovskite solar cell. The structure of the perovskite solar cell can include a PIN structure or an NIP structure. In embodiments, the thin conducting layer can provide semiconductor stability for the transport layer. The semiconductor stability can reduce diffusion between the transport layer and the metallic foil substrate. The providing the semiconductor stability can significantly increase the useful life of a perovskite solar cell, such as a flexible perovskite solar cell described herein. In other embodiments, a stabilization layer can be inserted between the transport layer and the perovskite layer (discussed below). The stabilization layer can further stabilize the perovskite layer and increase solar cell longevity. In embodiments, the stabilization layer can include (1,3-bis(diphenylphosphino)-propane) (DPPP). Various techniques can be used to form the stabilization layer. In embodiments, the stabilization layer can be inserted using a slot-coating process. The slot-coating process can include a high-precision deposition technique for depositing a thin liquid film onto a substrate. The substrate can be in motion underneath a slot-coating “head” or die. The thickness of the film such as the stabilization layer can be controlled by a flow rate, movement rate or speed, etc.

The flow 100 includes adding a perovskite layer 130 on the transport layer. The perovskite layer generates an electric current based on light energy impingement. The perovskite layer can generate an amount of current proportional to the amount of light energy that impinges on the perovskite layer. The perovskite layer can be added to the “stack-up” of layers described above using a variety of fabrication techniques. In embodiments, the adding can be based on deposition techniques. The deposition techniques can include sputtering, spin coating, chemical vapor deposition, and so on. The electric current that can be generated by the perovskite layer can comprise electrons and holes. The holes can be collected by the HTL layer on which the perovskite layer is added. The electrons can be collected by an additional transport layer such as an electron transport layer (ETL) described below. The perovskite layer can include a material such as a crystalline material, where the crystalline material can follow a formula such as ABX₃. In embodiments, the perovskite layer can be based on formamidinium lead iodide (FAPbI₃).

The flow 100 includes providing an additional transport layer 140 on the perovskite layer, wherein the additional transport layer complements the transport layer. A variety of deposition techniques can be used to provide the additional transport layer. The deposition techniques can include sputtering, spin coating, chemical vapor deposition, and so on. The deposition techniques that can be used to deposit the transport layer and the additional transport layer can include a substantially similar technique or a substantially different technique. As previously discussed, the transport layer described above can transport holes. Therefore, the additional transport layer can transport electrons. In embodiments, the additional transport layer comprises an electron transport layer (ETL). The ETL that is deposited on the perovskite layer can be based on a variety of materials. In embodiments, the ETL can include a tin(IV) oxide (SnO₂) layer. Further materials can be used for the additional transport layer. In other embodiments, the ETL can include a C₆₀ fullerene layer. Other suitable ETL layer materials can include Titanium Dioxide (TiO₂), [6,6]-Phenyl-C₆₁-butyric acid methyl ester (PCBM), Zinc Oxide (ZnO), Fullerenes and their derivatives (e.g., PCBM, C₆₀), Indium Gallium Zinc Oxide (IGZO), Tin Oxide (SnO₂), Tungsten Disulfide (WS₂), and Cerium Oxide (CeO₂).

One or more other layers can be deposited on the perovskite layer. The one or more additional layers can improve stability, performance, and longevity of a perovskite solar cell of which the perovskite layer is a component. The perovskite layer can be capped. In embodiments, a perovskite capping layer can be inserted between the perovskite layer and the additional transport layer. The capping layer can be used to passivate the perovskite layer. In embodiments, the perovskite capping layer can enable dangling bond passivation. Dangling bond passivation can be used to recombine carriers such as holes and electrons. The capping layer can provide reaction prevention. In embodiments, the perovskite capping layer can enable redox prevention. Redox, or oxidation-reduction, is a reaction in which electrons move between species. The capping layer can also provide electrical smoothing. In embodiments, the perovskite capping layer can enable a smoothed electric potential across the perovskite layer. The smoothing of electric potential across the perovskite layer can prevent electrical hotspots due to different local electrical potentials.

The flow 100 includes isolating the additional transport layer 150 with a conductive layer, wherein the conductive layer enables light transmission. The conductive layer that isolates the additional transport layer can improve transport of carriers such as electrons from the transport layer to other layers such as a grid layer, discussed below. The conductive layer enables light transmission through the conductive layer to layers below in the stack-up. The layers below include the perovskite layer discussed previously. The enabling light transmission can allow light to travel through the isolating layer and the ETL to the perovskite layer. Various conductive materials can be used for the conductive layer. In embodiments, the conductive layer can include a conductive oxide. Various oxides can be used for the conductive layer. In embodiments, the conducting layer can include a transparent conductive oxide (TCO). The TCO can enable electrons in the ETL to be conducted to a connecting layer (discussed below). The TCO can enable transmission of light through the conductive layer to the perovskite layer below. In other embodiments, the conductive layer can include a conductive polymer.

The flow 100 includes connecting a grid on the conductive layer 160, wherein the grid conducts electric current, and wherein the grid enables light energy to reach the perovskite layer. The conductive grid layer can include a metal layer which can be used to conduct charge carriers from the additional transport layer. In embodiments, the charge carriers associated with the additional transport layer can include electrons. That is, the conductive grid layer can conduct the electrons from the ETL. The conductive grid layer can include various metals such as aluminum (Al), chromium (Cr), copper (Cu), iron (Fe) and some alloys of steel, nickel (Ni), and so on. The conductive grid layer can enable the structure or stack-up comprising the substrate and the formed and deposited layers to remain rollable. The connecting layer can include a variety of patterns, shapes, and so on which enable conduction of electrons while permitting light to pass through to lower layers. The lower layers include the perovskite layer. The connecting layer can include the grid, a crisscross pattern, a honeycomb pattern, and so on. The connecting layer can be optimized to transfer various wavelengths of light, light bands such as a visible light band, and the like. The connecting layer can comprise a plurality of parallel lines. In embodiments, the grid can be formed on the conductive layer using screen printing. The screen printing can be combined with one or more deposition techniques in order to form the grid. The screen printing can include techniques that can be used in order to make the perovskite solar cells flexible. In embodiments, the screen printing can be performed flexographically to enable roll manufacturing.

In the flow 100, the grid and the metallic foil substrate form contacts 162 for photovoltaic operation. The contacts can enable access to a voltage, a current, etc. One or more photovoltaic cells can include the perovskite solar cells described above. The photovoltaic solar cells can be coupled in various electrical configurations such as a series configuration, a parallel configuration, and so on. In embodiments, one or more perovskite cells can be coupled in parallel. The advantage of coupling the perovskite cells in parallel is that if a cell fails, the remaining operating cells can continue to operate and provide a voltage, a current, etc. The photovoltaic operation can produce an output voltage. In embodiments, the photovoltaic operation produces an output voltage in a range of 0.5V to 1.5V. The output voltage can depend on the material chosen for the perovskite layer, the fabrication of the various layers associated with the perovskite layer, and so on. The perovskite solar cells can also produce an output current. In other embodiments, the photovoltaic operation produces an output current density greater than or equal to 20 mA/cm².

In the flow 100, the obtaining, the depositing, the adding, the providing, the isolating, and the connecting enable manufacture 170 of a flexible perovskite solar cell. The flexible perovskite solar cell offers a variety of manufacturing and photovoltaic solar cell deployment and usage advantages. In the flow 100, the flexible perovskite solar cell is produced in rolls 172. The production of the perovskite solar cell in rolls enables production of solar cells using existing industrial manufacturing equipment. The manufacturing equipment can include equipment for producing thin films, printing equipment, and so on. The flow 100 further includes arranging a plurality of flexible perovskite solar cells into a solar cell module 174. The perovskite solar cells can be associated with the same roll of solar cells or different rolls of solar cells. The solar cells can include cells of substantially similar sizes or substantially different sizes. The solar cell module can include cells connected in parallel. The parallel connection of the cells can enable an amount of current that can be produced by the module. In embodiments, the solar cell module can include a series connection of the flexible perovskite solar cells. The series connection of the flexible perovskite solar cells can be used to achieve a desired voltage.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

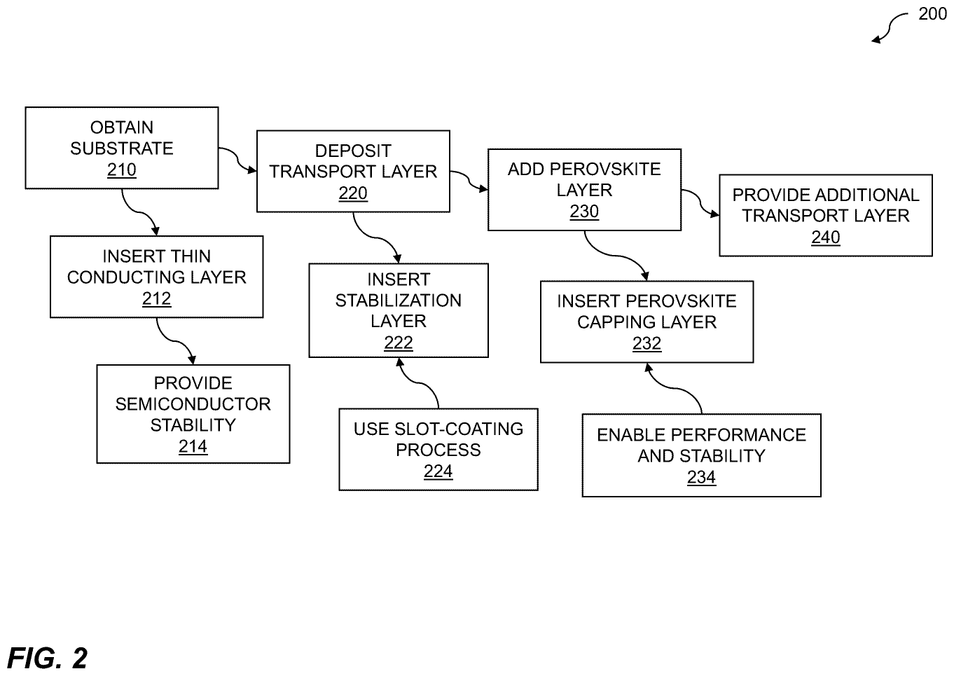

FIG. 2 is a flow diagram for stabilizing a flexible perovskite solar cell using a conductive grid. The basic structure of a flexible perovskite solar cell comprises conducting layers that can be used as terminals, transport layers for collecting electrons and holes, and a perovskite layer for converting light energy into electrical energy. In addition to these layers, further layers can be added to the “stack-up”, where the additional layers enhance solar cell performance by improving charge conduction; stabilizing layers of the perovskite solar cell with respect to electrical, electronic, and materials parameters; and so on. The stabilizing enables a flexible perovskite solar cell using a conductive grid. A metallic foil substrate is obtained, wherein the metallic foil substrate is flexible and rollable. A transport layer is deposited on the metallic foil substrate, wherein the transport layer enables current conduction to the metallic foil substrate. A perovskite layer is added on the transport layer, wherein the perovskite layer generates an electric current based on light energy impingement. An additional transport layer is provided on the perovskite layer, wherein the additional transport layer complements the transport layer. The additional transport layer is isolated with a conductive layer, wherein the conductive layer enables light transmission. A grid is connected on the conductive layer, wherein the grid conducts electric current, wherein the grid enables light energy to reach the perovskite layer, and wherein the grid and the metallic foil substrate form contacts for photovoltaic operation.

The flow 200 includes obtaining a metallic foil substrate 210. The metallic foil substrate can include a backing such as a plastic backing. The metallic foil substrate is flexible and rollable. The metallic foil substrate can be based on a variety of metals. The variety of metals can include aluminum (Al), chromium (Cr), copper (Cu), iron (Fe) and some alloys of steel, nickel (Ni), and so on. The metal foil can be sufficiently thin so as to be relatively lightweight and rollable. Gold, silver, and platinum can be prohibitively expensive, so the former metals can be preferred. In addition to the cost, silver tarnishes, thereby reducing the reliability of a solar cell. In the flow 200, a thin conducting layer 212 is inserted between the metallic foil substrate and a transport layer (described below). The transport layer can transport electrical charges, where the electrical charges can include holes (positive charge) or electrons (negative charge). The transport layer can include a hole transport layer or an electron transport layer, respectively. The thin conduction layer can be inserted between the metallic foil substrate conducting layer and the transport layer. The transport layer can depend on the structure of a perovskite solar cell. The structure of the perovskite solar cell can include a PIN structure or an NIP structure. In the flow 200, the thin conducting layer can provide semiconductor stability 214 for the transport layer. The semiconductor stability can reduce diffusion between the transport layer and the metallic foil substrate. The semiconductor stability can increase the useful life of the perovskite solar cell.

The flow 200 includes depositing a transport layer 220 on the metallic foil substrate, wherein the transport layer enables current conduction to the metallic foil substrate. The transport layer that is deposited is dependent on the layering of the perovskite solar cell. The layering can include an NIP layering or a PIN layering. For the NIP layering, the transport layer can include an electron transport layer (ETL). The electron transport layer can transport electrons generated by a charge generation layer such as a perovskite layer (described below). For the PIN layering, the transport layer can include a hole transport layer (HTL). The hole transport layer can transport holes generated by a charge generation layer. In embodiments, the ETL can include a tin (IV) oxide (SnO₂) layer. The chosen ETL material can be selected to maximize transport of electrons generated by the perovskite layer. The ETL layer can be formed using one or more other materials. In embodiments, the ETL can include a C₆₀ fullerene layer. The fullerene layer can be chosen due to its charge transport efficacy and high electron affinity. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport.

In the flow 200, a stabilization layer can be inserted 222 between the transport layer and a perovskite layer (discussed below). The stabilization layer can further stabilize the perovskite layer and increase solar cell longevity. The stabilization layer can comprise a variety of materials. In embodiments, the stabilization layer can include (1,3-bis(diphenylphosphino)-propane) (DPPP). In the flow 200, the stabilization layer can be inserted using a slot-coating 224 process. The slot-coating process can include a high-precision technique for depositing a thin liquid film onto a substrate. The substrate can be in motion underneath a slot-coating “head” or die. The thickness of the film such as the stabilization layer can be controlled by a flow rate, movement rate or speed, etc.

The flow 200 includes adding a perovskite layer 230 on the transport layer. Noted above and throughout, the perovskite layer generates an electric current based on light energy impingement. A variety of adding techniques can be used to add the perovskite layer onto the transport layer. In embodiments, the adding can be based on deposition techniques. The deposition techniques can include sputtering, spin coating, chemical vapor deposition, and so on. The electric current that can be generated by the perovskite layer can comprise electrons and holes. The holes can be collected by the HTL layer or the ETL on which the perovskite layer is added. For the opposite carriers, either electrons or holes can be collected by an additional transport layer, described below. The perovskite layer can include a material such as a crystalline material, where the crystalline material can follow a formula such as ABX₃.

In the flow 200, a perovskite capping layer is inserted 232 between the perovskite layer and the additional transport layer. The capping layer can be inserted using a variety of fabrication techniques such as sputtering, spin coating, chemical vapor deposition, etc. In the flow 200, using the capping layer enables improved performance and stability 234 of the perovskite layer. The improved performance and stability can include improvements to chemical, electrical, and mechanical performance and stability. The capping layer can be inserted between the perovskite layer and another layer within the stack-up. In embodiments, the perovskite capping layer can be inserted between the perovskite layer and an additional transport layer (discussed below). The capping layer can be used to passivate the perovskite layer. In embodiments, the perovskite capping layer can enable dangling bond passivation. The capping layer can enable reduction or prevention of a variety of reactions. Reaction prevention can improve the long-term stability and useful life of the perovskite layer. In embodiments, the perovskite capping layer can enable redox prevention. Redox, or oxidation-reduction, is a reaction in which electrons move between chemical species. The capping layer can also provide electrical smoothing across the perovskite layer. In embodiments, the perovskite capping layer can enable a smoothed electric potential across the perovskite layer. The smoothing of electric potential across the perovskite layer can prevent electrical “hotspots” across the perovskite layer due to local differences of electrical potentials, current densities, and so on.

The flow 200 includes providing an additional transport layer 240 on the perovskite layer, wherein the additional transport layer complements the transport layer. The additional transport layer can include an electron transport layer or a hole transport layer. When the transport layer (discussed above) is a hole transport layer (HTL), then the additional transport layer comprises an electron transport layer (ETL). That is, the additional transport layer complements the transport layer. The additional transport layer that is provided can be deposited using various deposition techniques. The deposition techniques can include sputtering, spin coating, chemical vapor deposition, etc. The deposited ETL can be based on a variety of materials. In embodiments, the ETL can include a tin(IV) oxide (SnO₂) layer. Other materials can also be used. In other embodiments, the ETL can include a C₆₀ fullerene layer. In embodiments, perovskite layer can be capped, where the perovskite capping layer can be inserted between the perovskite layer and the additional transport layer.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

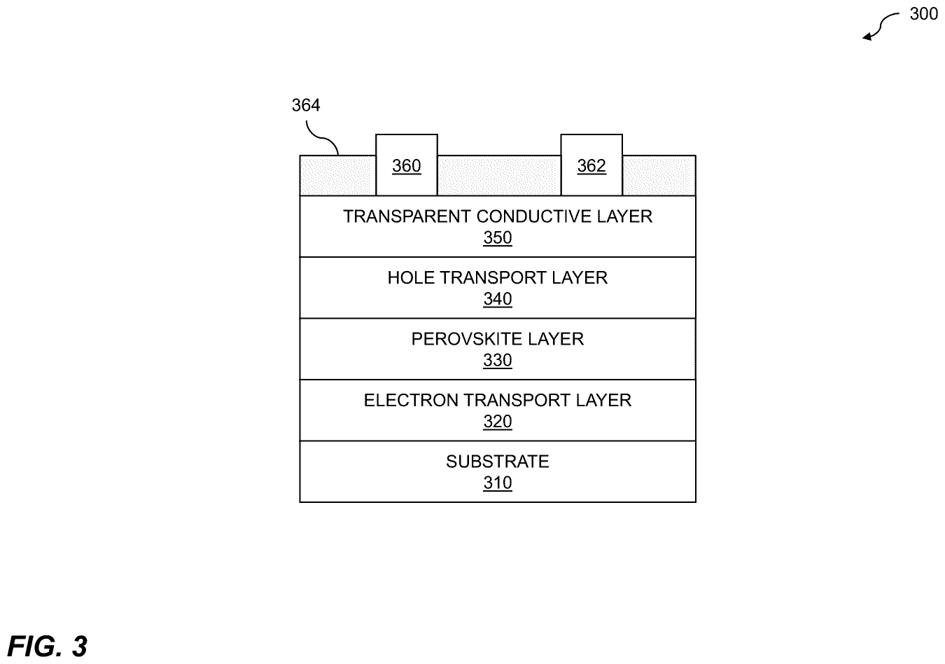

FIG. 3 is an infographic for NIP layering. The NIP layering can be associated with a flexible perovskite solar cell using a conductive grid. The infographic 300 shows an example flexible perovskite solar stack-up comprising a plurality of layers. In this example stack-up, a perovskite layer is placed onto an electron transport layer, and a hole transport layer is placed onto the perovskite layer. The layering forms an NIP stack-up. The NIP layering of the materials enables a flexible perovskite solar cell using a conductive grid. A metallic foil substrate is obtained, wherein the metallic foil substrate is flexible and rollable. A transport layer is deposited on the metallic foil substrate, wherein the transport layer enables current conduction to the metallic foil substrate. A perovskite layer is added on the transport layer, wherein the perovskite layer generates an electric current based on light energy impingement. An additional transport layer is provided on the perovskite layer, wherein the additional transport layer complements the transport layer. The additional transport layer is isolated with a conductive layer, wherein the conductive layer enables light transmission. A grid is connected on the conductive layer, wherein the grid conducts electric current, wherein the grid enables light energy to reach the perovskite layer, and wherein the grid and the metallic foil substrate form contacts for photovoltaic operation.

A flexible perovskite solar cell can be constructed by layering a plurality of materials. The layering materials can comprise NIP layering. The layering can include a conductive metal substrate 310. The conductive metal substrate can be used as a terminal associated with the NIP layering. The conductive metal substrate can include a flexible metal substrate. In embodiments, the conductive metal substrate can include a metallic foil substrate. The metallic foil substrate can include various metals such as aluminum (Al), chromium (Cr), copper (Cu), iron (Fe) and some alloys of steel, nickel (Ni), and so on. The metal foil can be sufficiently thin to be relatively lightweight and rollable. While gold and platinum are excellent conductors, their cost is prohibitive. Silver is also relatively expensive and has the additional disadvantage of easily tarnishing, thereby rendering silver less stable than other metals. Because of these issues, other elements or alloys can be used. The NIP layering can include an electron transport layer (ETL) 320. The electron transport layer can transport electrons generated by a charge generation layer. The ETL can enable transport of electrons generated by a perovskite layer (described below). In embodiments, the ETL can include a tin(IV) oxide (SnO₂) layer. The chosen ETL material can be selected to maximize transport of electrons generated by the perovskite layer. The ETL layer can be formed using one or more other materials. In embodiments, the ETL can include a C₆₀ fullerene layer. The fullerene layer can be chosen due to its charge transport efficacy and high electron affinity.

The NIP layering can include a perovskite layer 330. The perovskite layer can be used to convert light energy such as sunlight energy to electrical energy. The perovskite layer can generate an electric current based on light energy impingement. The perovskite layer can be added onto the electron transport layer using various deposition techniques. The deposition techniques can include sputtering, spin coating, chemical vapor deposition, and so on. The electric current generated by the perovskite layer can comprise electrons and holes. The electrons can be collected by the ETL layer on which the perovskite layer is added. The holes can be collected by an additional transport layer, a hole transport layer (HTL), described below. The perovskite layer can be based on a crystalline material, where the crystalline material can follow an ABX₃ formula. In embodiments, the perovskite layer can be based on formamidinium lead iodide (FAPbI₃). The FAPbI₃ can be chosen for the perovskite layer due to its higher chemical, moisture, and thermal stability parameters.

The layering can include a hole transport layer (HTL) 340. The holes generated by the perovskite layers can be transported from the perovskite layer to an additional conductive layer, where the additional conductive layer includes a hole transport layer. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport. The NIP layering can include a transparent conductive oxide (TCO) layer 350. The TCO can both conduct charges such as electrons and enable light such as sunlight to pass through the layer to further layers in the layering. The further layers can include the additional transport layer, the perovskite layer, and so on. A variety of materials can be used to enable the TCO. The TCO materials can include indium tin oxide, metal grids, graphene, conductive polymers, nanowire meshes, carbon nanotubes, metal films including ultra-thin metal films, and so on. The TCO can be chosen to maximize transmission of light such as visible light through the TCO to the perovskite layer.

The layering of the NIP materials can include a conducting grid. The conducting grid can be used as a second terminal for the NIP layering. The conducting grid can include parallel lines such as line 360 and line 362. In embodiments, the conducting grid can further include intersecting parallel lines such as line 364. The grid can comprise solely parallel lines, parallel lines and crisscrossing parallel lines, concentric rings, various patterns, and so on. The grid can include a square pattern grid, a diamond grid, a honeycomb grid, etc. The grid can conduct electric current such as holes produced by a perovskite solar cell. In embodiments, the grid can enable light energy to reach additional layers in the NIP layering such as the hole transport layer. The grid can be based on one or more conducting materials. The grid can be formed using techniques such as material deposition techniques, printing techniques, etc. In embodiments, the grid can be formed on a conductive layer using screen printing. The grid can be printed to enable light to pass through it, where the light can be based on one or more wavelengths of light, a light band such as the visible light band, and so on. The screen printing can enable the NIP layering to be flexible. In embodiments, the screen printing can be performed flexographically to enable roll manufacturing. The roll manufacturing enables flexibility of the solar cell so that the solar cell can be rolled up during manufacturing, unrolled for use, rerolled for transport or storage, and so on.

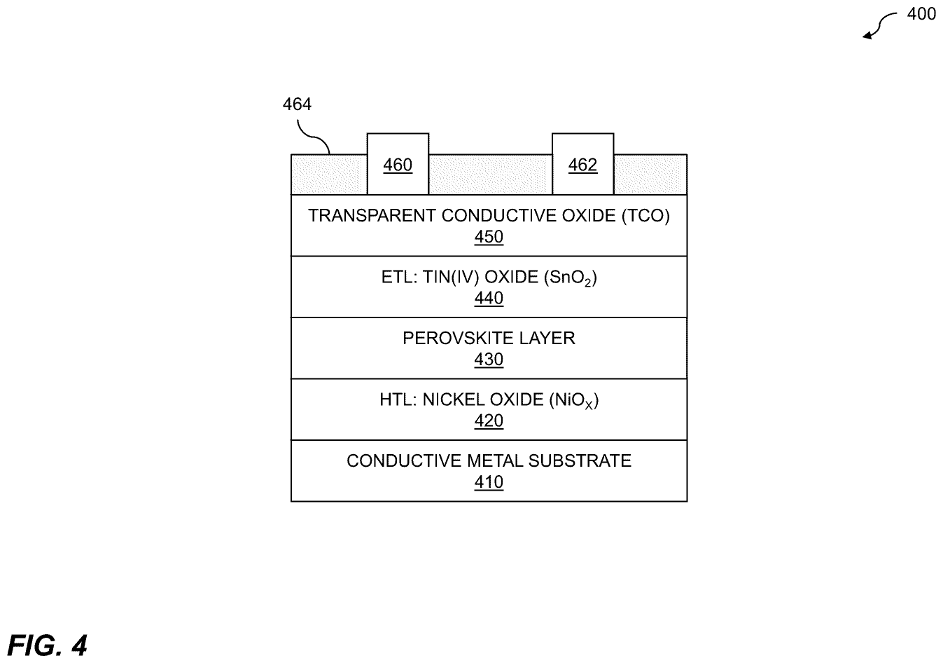

FIG. 4 is an infographic for layering PIN materials in a flexible perovskite solar cell using a conductive grid. The figure shows an alternative configuration for a flexible perovskite solar cell stack-up. In this configuration, a perovskite layer is placed onto a hole transport layer, and an electron transport layer is placed onto the perovskite layer, thus forming a PIN stack-up. The layering of PIN materials enables a flexible perovskite solar cell using a conductive grid. A metallic foil substrate is obtained, wherein the metallic foil substrate is flexible and rollable. A transport layer is deposited on the metallic foil substrate, wherein the transport layer enables current conduction to the metallic foil substrate. A perovskite layer is added onto the transport layer, wherein the perovskite layer generates an electric current based on light energy impingement. An additional transport layer is provided on the perovskite layer, wherein the additional transport layer complements the transport layer. The additional transport layer is isolated with a conductive layer, wherein the conductive layer enables light transmission. A grid is connected on the conductive layer, wherein the grid conducts electric current, wherein the grid enables light energy to reach the perovskite layer, and wherein the grid and the metallic foil substrate form contacts for photovoltaic operation.

The layering of PIN materials can be performed using techniques which are substantially similar to layering NIP materials. The layering 400 can include a conductive metal substrate 410. In embodiments, the conductive metal substrate can include a metallic foil substrate. The metals can include silver (Ag), gold (Au), or platinum (Pt), which are excellent conductors. However, the cost of each of these metals is prohibitive. In addition, silver can cause long term reliability and stability challenges because of its propensity to tarnish. Other metals that can be used for the metallic foil substrate can include aluminum (Al), chromium (Cr), copper (Cu), iron (Fe) and some alloys of steel, nickel (Ni), and so on. The metal foil can be sufficiently thin to be relatively lightweight and rollable. The layering 400 can include a hole transport layer (HTL) 420. The hole transport layer can transport holes generated by a charge generation layer. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport.

The layering 400 can include a perovskite layer 430. The perovskite layer can be used to convert light energy such as sunlight energy to electrical energy. The perovskite layer can generate an electric current based on light energy impingement. The perovskite layer can be added on the transport layer using various deposition techniques. The deposition techniques can include sputtering, spin coating, chemical vapor deposition, and so on. The electric current generated by the perovskite layer can comprise electrons and holes. The holes can be collected by the HTL layer on which the perovskite layer is added. The electrons can be collected by an electron transport layer (ETL) described below.

The layering 400 can include an electron transport layer (ETL) 440. The ETL can enable transport of electrons generated by the perovskite layer. The electrons generated by the perovskite layers can be transported from the perovskite layer to an additional conductive layer. In embodiments, the ETL can include a tin(IV) oxide (SnO₂) layer. The chosen ETL material can be selected to maximize transport of electrons generated by the perovskite layer. The ETL layer can be formed using one or more other materials. In embodiments, the ETL can include a C₆₀ fullerene layer. The fullerene layer can be chosen due to its charge transport efficacy and high electron affinity. The layering 400 can include a transparent conductive oxide (TCO) 450. The TCO can both conduct charges such as electrons and enable light such as sunlight to pass through the layer to further layers in the layering. The further layers can include the additional transport layer, the perovskite layer, and so on. A variety of materials can be used to enable the TCO. The TCO materials can include indium tin oxide (In₂O₃/SnO₂), metal grids, graphene, conductive polymers, nanowire meshes, carbon nanotubes, metal films including ultra-thin metal films, and so on. The TCO can be chosen to maximize transmission of light such as visible light through the TCO to the perovskite layer.

The layering of PIN materials can include a conducting grid. The conducting grid can include parallel lines such as line 460 and line 462. In embodiments, the conducting grid can further include intersecting parallel lines 464 that intersect perpendicularly with parallel lines 460 and 462. Non-perpendicular intersections can also be implemented. The grid can comprise solely parallel lines, parallel lines and crisscrossing parallel lines, concentric rings, and so on. The grid can include a square pattern grid, a diamond grid, a honeycomb grid, etc. The grid can conduct electric current such as electrons produced by a perovskite solar cell. In embodiments, the grid can enable light energy to reach additional layers in the PIN layering such as the electron transport layer. The grid can be based on one or more conducting materials. The grid can be formed using techniques such as deposition techniques, printing techniques, and the like. In embodiments, the grid can be formed on a conductive layer using screen printing. The grid can be printed to enable light to pass through it, where the light can be based on one or more wavelengths of light, a light band such as the visible light band, etc. The grid can be screen printed. The screen printing can enable the PIN layering to be flexible. In embodiments, the screen printing can be performed flexographically to enable roll manufacturing. The roll manufacturing enables flexibility of the solar cell so that the solar cell can be rolled up.

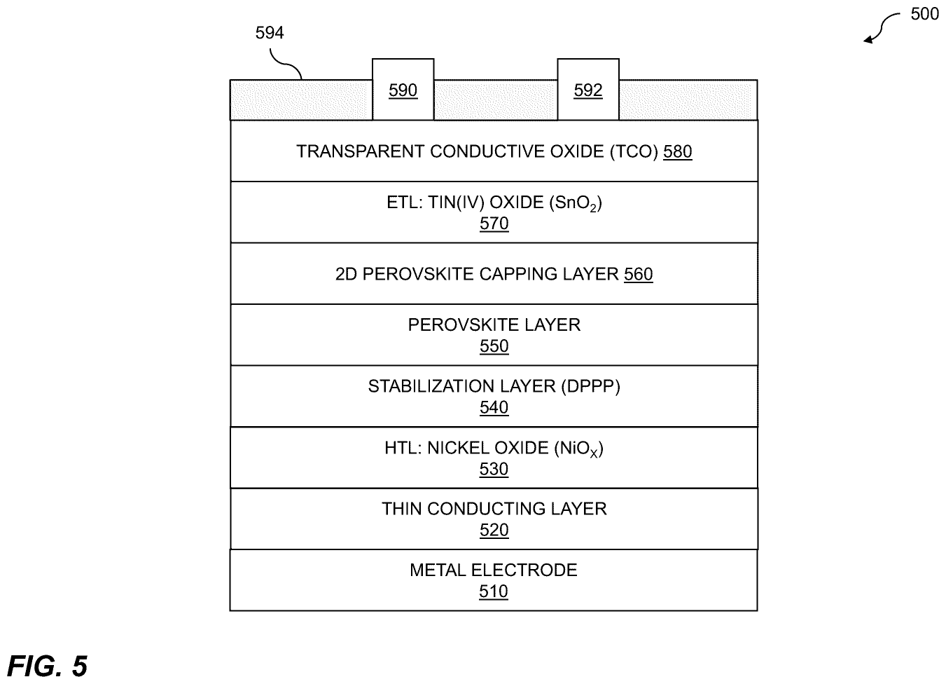

FIG. 5 is an infographic for a full stack-up of a flexible perovskite solar cell using a conductive grid. The full stack-up shows the various material layers, including a perovskite layer that can be deposited, coated, and so on to produce a flexible perovskite solar cell. The various layers, in addition to the perovskite layer, can include transport layers, conductive layers, and so on. The layers of the full stack-up enable a flexible perovskite solar cell using a conductive grid. A metallic foil substrate is obtained, wherein the metallic foil substrate is flexible and rollable. A transport layer is deposited on the metallic foil substrate, wherein the transport layer enables current conduction to the metallic foil substrate. A perovskite layer is added on the transport layer, wherein the perovskite layer generates an electric current based on light energy impingement. An additional transport layer is provided on the perovskite layer, wherein the additional transport layer complements the transport layer. The additional transport layer is isolated with a conductive layer, wherein the conductive layer enables light transmission. A grid is connected on the conductive layer, wherein the grid conducts electric current, wherein the grid enables light energy to reach the perovskite layer, and wherein the grid and the metallic foil substrate form contacts for photovoltaic operation.

The full stack-up 500 can include a metal electrode 510. The metal electrode can form a terminal of a stack-up such as a stack-up associated with a solar cell. The solar cell can include a perovskite solar cell (PSC). The metal electrode can include a supporting layer, substrate, and so on for the PSC. In embodiments, the metal electrode can include a metallic foil substrate. The metallic foil substrate can serve as a standalone layer. The metallic foil substrate can be mounted to a backing layer such as a plastic backing layer, or can remain unmounted. In embodiments, the metallic foil substrate can be flexible and rollable. The flexible and rollable metallic foil enables rolling of the stack-up during manufacturing of the PSC. The flexible and rollable metallic foil enables unrolling and rolling of the PSC after manufacturing of the PSC. The full stack-up 500 can include a thin conducting layer 520. The thin conducting layer can enable conduction of carriers between layers within the stack-up. In embodiments, the thin conducting layer can be inserted between the metallic foil substrate and the transport layer (discussed below). The thin conducting layer can be used to improve one or more performance parameters associated with the PSC stack-up. In embodiments, the thin conducting layer can provide semiconductor stability for the transport layer. The carriers can be conducted by the thin conducting layer and can include holes or positive charges, and electrons or negative charges. The full stack-up 500 can include a buffer layer between the metal substrate and an adjacent transport layer to provide additional stability and reliability.

The full stack-up 500 can include a hole transport layer (HTL) 530. A transport layer can transport holes or electrons. A hole transport layer can transport electrical charges such as positive charges or holes generated by a perovskite layer (discussed below). A variety of materials can be used for the HTL. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport. The full stack-up 500 can include a stabilization layer 540. The stabilization layer can be used to stabilize the hole transport layer, the interface between the HTL and another layer such as a perovskite layer, and so on. The stabilization layer can be formed from a variety of materials. In embodiments, the stabilization layer can include (1,3-bis(diphenylphosphino)-propane) (DPPP). The stabilization layer can be inserted between layers of the full stack-up. In embodiments, a stabilization layer is inserted between the transport layer and a perovskite layer (discussed below). The stabilization layer can be deposited, printed, etc. In embodiments, the stabilization layer is inserted using a slot-coating process.

The full stack-up 500 can include a perovskite layer 550. The perovskite layer can be added onto the transport layer described above. The perovskite layer can convert light energy such as sunlight energy to electrical energy. An efficiency percentage, a power conversion efficiency (PCE), can be calculated for the power conversion. The perovskite layer can generate an electric current based on light energy impingement. The perovskite layer can be added onto the transport layer using various techniques. In embodiments, the adding can be based on deposition techniques. The deposition techniques can include sputtering, spin coating, chemical vapor deposition, and so on. The electric current generated by the perovskite layer can comprise electrons and holes. The holes can be collected by the HTL layer on which the perovskite layer is added. The electrons can be collected by an electron transport layer (ETL) described below.

The full stack-up can include a two-dimension (2D) perovskite capping layer 560. The capping layer can be used to increase the stability of the perovskite layer. The capping layer can be inserted between the perovskite layer and another layer within the stack-up. In embodiments, the perovskite capping layer can be inserted between the perovskite layer and an additional transport layer (discussed below). The capping layer can be used to passivate the perovskite layer. In embodiments, the perovskite capping layer can enable dangling bond passivation. The capping layer can provide reaction prevention. Reaction prevention can improve the long-term stability and useful life of the perovskite layer. In embodiments, the perovskite capping layer can enable redox prevention. Redox, or oxidation-reduction, is a reaction in which electrons move between species. The capping layer can also provide electrical smoothing across the perovskite layer. In embodiments, the perovskite capping layer can enable a smoothed electric potential across the perovskite layer. The smoothing of electric potential across the perovskite layer can prevent electrical hotspots due to different local electrical potentials, current densities, and so on.

The full stack-up 500 can include an electron transport layer (ETL) 570. The ETL can transport electrons generated by an electron source such as the perovskite layer (described above). The ETL can be formed from a variety of materials. In embodiments, the ETL can include a tin(IV) oxide (SnO₂) layer. The material chosen for the ETL can be chosen to maximize transport of electrons generated by the perovskite layer. Other materials can also be used for the ETL. In embodiments, the ETL can include a C₆₀ fullerene layer. The fullerene layer can be produced due to its high electron affinity and its charge transport efficiently. The full stack-up 500 can include a transparent conductive oxide (TCO) 580. The TCO can enable light such as sunlight to pass through the layer to further layers in the stack-up. The further layers can include the additional transport layer, the perovskite layer, and so on. Various materials can be used to enable the TCO. The TCO materials can include indium tin oxide, metal grids, graphene, conductive polymers, nanowire meshes, carbon nanotubes, metal films including ultra-thin metal films, and so on. The TCO can be chosen to maximize transmission of light such as visible light through the TCO.

The full stack-up 500 of a flexible perovskite solar cell can include a conducting grid. The conducting can include parallel lines such as line 590 and line 592, and intersecting lines such as line 594. The grid can comprise solely parallel lines, parallel lines and crisscrossing parallel lines, and so on. The grid can include a square pattern grid, a diamond grid, a honeycomb grid, and the like. The grid can conduct electric current produced by a perovskite solar cell. In embodiments, the grid can enable light energy to reach additional layers in the stack-up such as the additional transport layer (discussed above). The grid can be based on one or more conducting materials. The grid can be formed using one or more techniques such as deposition techniques, printing techniques, and the like. In embodiments, the grid can be formed on a conductive layer using screen printing. The grid can be printed to enable light to pass through it, where the light can be based on one or more wavelengths of light, a light band such as the visible light band, etc. The grid can be screen printed such that the stack-up can be flexible. In embodiments, the screen printing can be performed flexographically to enable roll manufacturing. The roll manufacturing enables flexibility of the solar cell so that the solar cell can be rolled up.

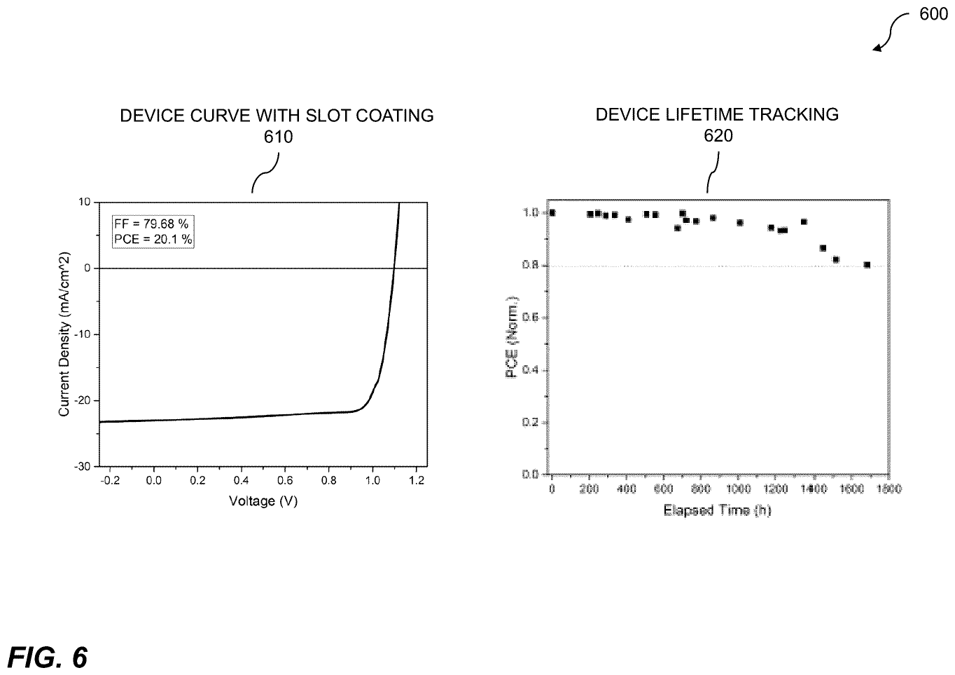

FIG. 6 illustrates graphs of flexible perovskite solar cell performance. The performance of a perovskite solar cell can be associated with one or more parameters. The parameters can include size, weight, voltage and current output, voltage and current stability, cycle lifetime for rolling and unrolling the solar panels, cell stability, and so on. By determining the performance of the perovskite solar cell with respect to one or more parameters, an overall quality of the perovskite solar cell can be determined. Furthermore, the parameters can be used to tune one or more fabrication steps used to construct the perovskite solar cell. By tuning, adjusting, or substituting one or more fabrication steps, the overall performance of the perovskite solar cell can be further improved, optimized, etc. The perovskite solar cell performance enables a flexible perovskite solar cell using a conductive grid. A metallic foil substrate is obtained, wherein the metallic foil substrate is flexible and rollable. A transport layer is deposited on the metallic foil substrate, wherein the transport layer enables current conduction to the metallic foil substrate. A perovskite layer is added on the transport layer, wherein the perovskite layer generates an electric current based on light energy impingement. An additional transport layer is provided on the perovskite layer, wherein the additional transport layer complements the transport layer. The additional transport layer is isolated with a conductive layer, wherein the conductive layer enables light transmission. A grid is connected on the conductive layer, wherein the grid conducts electric current, wherein the grid enables light energy to reach the perovskite layer, and wherein the grid and the metallic foil substrate form contacts for photovoltaic operation.

Graphs for two performance parameters associated with perovskite solar cell performance are shown 600. A perovskite solar cell (PSC) current (I or J) versus voltage (V) device curve is shown 610. The PSC for which current versus voltage is plotted can include a PSC fabricated using a slot coating technique. A slot coating technique can be used to “print” a thin film layer while fabricating a perovskite solar cell. Recall that a stabilization layer can be inserted between a transport layer and a perovskite layer. In embodiments, the stabilization layer can be inserted using a slot-coating process. The stabilization layer can comprise a variety of materials. In embodiments, the stabilization layer can include DPPP (1,3-bis(diphenylphosphino)-propane). The perovskite solar cell for which the current-voltage curve is plotted has a power-conversion efficiency (PCE) of 20.1%. Further, a fill factor (FF) can be determined for the PSC. The FF can be used to determine a maximum power for a solar cell. The FF associated with the PSC is 79.68%. A further graph shows device lifetime tracking 620. The device lifetime tracking can track power conversion efficiency versus elapsed time. The device lifetime tracking can be associated with PSC longevity. The longevity can be based on mechanical and electrical stability of the cell.

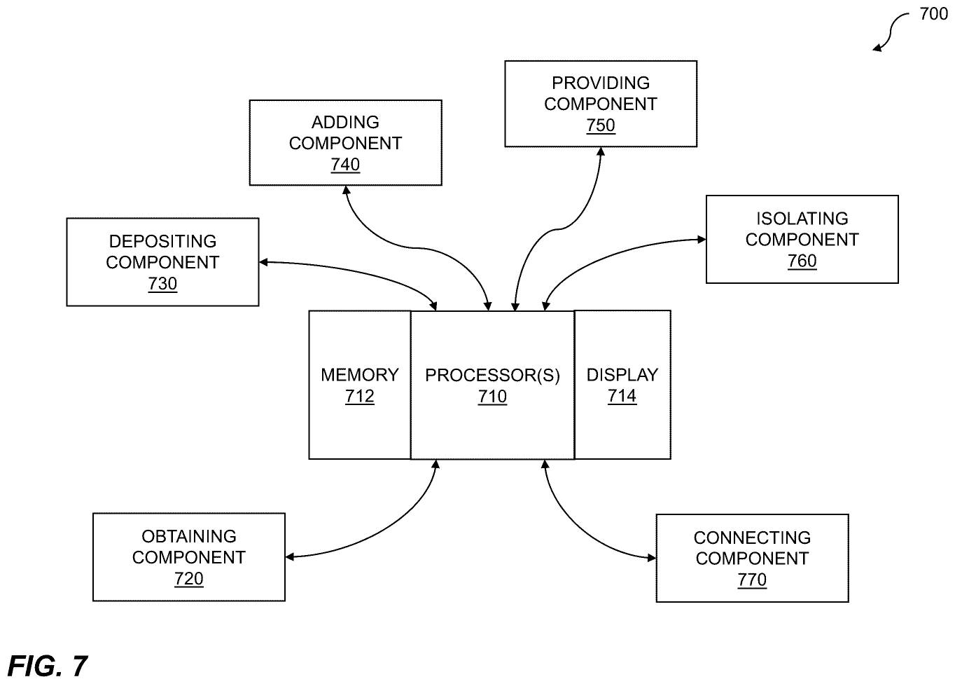

FIG. 7 is a system diagram for solar cell realization. The solar cell realization is enabled by a flexible perovskite solar cell using a conductive grid. The system 700 can include one or more processors 710, which are attached to a memory 712 which stores instructions. The system 700 can further include a display 714 coupled to the one or more processors 710 for displaying data, intermediate steps, metallic foil substrate parameters, deposition characteristics for transport layers, perovskite layer parameters, and so on. In embodiments, one or more processors 710 are coupled to the memory 712, wherein the one or more processors, when executing the instructions which are stored, are configured to: obtain a metallic foil substrate, wherein the metallic foil substrate is flexible and rollable; deposit a transport layer on the metallic foil substrate, wherein the transport layer enables current conduction to the metallic foil substrate; add a perovskite layer onto the transport layer, wherein the perovskite layer generates an electric current based on light energy impingement; provide an additional transport layer on the perovskite layer, wherein the additional transport layer complements the transport layer; isolate the additional transport layer with a conductive layer, wherein the conductive layer enables light transmission; and connect a grid on the conductive layer, wherein the grid conducts electric current, wherein the grid enables light energy to reach the perovskite layer, and wherein the grid and the metallic foil substrate form contacts for photovoltaic operation.

The system 700 can include an obtaining component 720. The obtaining component can obtain a metallic foil substrate, wherein the metallic foil substrate is flexible and rollable. A metallic foil substrate can be based on a variety of metals. The variety of metals can include aluminum (Al), chromium (Cr), copper (Cu), iron (Fe) and some alloys of steel, nickel (Ni), and so on. Gold, silver, and platinum can be prohibitively expensive, so the former metals can be preferred. In addition to the cost, silver tarnishes, thereby reducing the reliability of a solar cell. The metal foil can be sufficiently thin to be relatively lightweight and rollable. The system 700 can include a depositing component 730. The depositing component can deposit a transport layer on the metallic foil substrate, wherein the transport layer enables current conduction to the metallic foil substrate. The depositing can be accomplished using a variety of deposition techniques. In embodiments, the depositing can be accomplished using a sputtering technique. A transport layer can transport holes or electrons. In embodiments, the transport layer can include a hole transport layer (HTL). A variety of materials can be used for the HTL. In embodiments, the HTL can include a nickel oxide (NiOₓ) layer. Other materials can also be used for the deposited HTL. In other embodiments, the HTL comprises a poly[bis(4-phenyl)(2,4,6-trimethylphenyl)amine (PTAA) layer. The PTAA layer can be used individually or in conjunction with one or more further layers. In embodiments, the PTAA layer can be used in conjunction with a nickel oxide (NiOₓ) layer to form a composite HTL. The use of the nickel oxide layer can enhance hole transport.

In embodiments, a thin conducting layer can be inserted between the metallic foil substrate and the transport layer. The transport layer can include a hole transport layer or an electron transport layer. The transport layer to which the thin conduction layer can be inserted can depend on the structure of a perovskite solar cell. The structure of the perovskite solar cell can include a PIN structure or an NIP structure. In embodiments, the thin conducting layer can provide semiconductor stability for the transport layer. The semiconductor stability can reduce diffusion of the transport layer and the metallic foil substrate. The semiconductor stability can increase the useful life of the perovskite solar cell. In other embodiments, a stabilization layer can be inserted between the transport layer and the perovskite layer. The stabilization layer can further stabilize the perovskite layer and increase solar cell longevity. In embodiments, the stabilization layer can include DPPP (1,3-bis(diphenylphosphino)-propane). Various techniques can be used to form the stabilization layer. In embodiments, the stabilization layer can be inserted using a slot-coating process.

The system 700 can include an adding component 740. The adding component can add a perovskite layer onto the transport layer, wherein the perovskite layer generates an electric current based on light energy impingement. Various techniques can be used to add the perovskite layer onto the transport layer. In embodiments, the adding can be based on deposition techniques. The deposition techniques can include sputtering, spin coating, chemical vapor deposition, and so on. The electric current that can be generated by the perovskite layer can comprise electrons and holes. The holes can be collected by the HTL layer on which the perovskite layer is added. The electrons can be collected by an electron transport layer (ETL) described below. The perovskite layer can include a material such as a crystalline material, where the crystalline material can follow a formula such as ABX₃.

The system 700 can include a providing component 750. The providing component can provide an additional transport layer on the perovskite layer, wherein the additional transport layer complements the transport layer. The additional transport layer that is provided can be deposited using various deposition techniques. The deposition techniques can include sputtering, spin coating, chemical vapor deposition, etc. The deposition techniques used to deposit the transport layer and the additional transport layer can include a substantially similar technique or a substantially different technique. While the transport layer described above can transport holes, the additional transport layer can transport electrons. In embodiments, the additional transport layer comprises an electron transport layer (ETL). The deposited ETL can be based on a variety of materials. In embodiments, the ETL can include a tin (IV) oxide (SnO₂) layer. Other materials can also be used. In other embodiments, the ETL can include a C₆₀ fullerene layer. The perovskite layer can be capped. In embodiments, a perovskite capping layer can be inserted between the perovskite layer and the additional transport layer. The capping layer can be used to passivate the perovskite layer. In embodiments, the perovskite capping layer can enable dangling bond passivation. The capping layer can provide reaction prevention. In embodiments, the perovskite capping layer can enable redox prevention. Redox, or oxidation-reduction, is a reaction in which electrons move between species. The capping layer can also provide electrical smoothing. In embodiments, the perovskite capping layer can enable a smoothed electric potential across the perovskite layer. The smoothing of electric potential across the perovskite layer can prevent electrical hotspots due to different local electrical potentials.

The system 700 can include an isolating component 760. The isolating component can isolate the additional transport layer with a conductive layer, wherein the conductive layer enables light transmission. The enabling light transmission can allow light to travel through the isolating layer and the ETL to the perovskite layer. In embodiments, the conductive layer can include a conductive oxide. Various oxides can be used for the conductive layer. In embodiments, the conducting layer can include a transparent conductive oxide (TCO). The TCO can enable electrons in the ETL to be conducted to a connecting layer. The TCO can enable transmission of light through the conductive layer to the perovskite layer below. In other embodiments, the conductive layer can include a conductive polymer.

The system 700 can include a connecting component 770. The connecting component can connect a grid on the conductive layer, wherein the grid conducts electric current, wherein the grid enables light energy to reach the perovskite layer, and wherein the grid and the metallic foil substrate form contacts for photovoltaic operation. The conductive layer can include a metal layer which can be used to conduct the electrons from the ETL. The conductive layer can include conductive metals such as aluminum (Al), chromium (Cr), copper (Cu), iron (Fe) and some alloys of steel, nickel (Ni), and so on. The conductive layer can enable the structure comprising the substrate and the formed and deposited layers to remain rollable. The connecting layer can include a variety of patterns, shapes, and so on which enable conduction of electrons while permitting light to pass through to lower layers. The lower layers include the perovskite layer. The connecting layer can include the grid, a crisscross pattern, a honeycomb pattern, and so on. The connecting layer can be optimized to transfer various wavelengths of light, light bands such as a visible light band, and the like. The connecting layer can comprise a plurality of parallel lines. In embodiments, the grid can be formed on the conductive layer using screen printing. The screen printing can be combined with one or more deposition techniques in order to form the grid. The screen printing can include techniques that can make the perovskite solar cells flexible. In embodiments, the screen printing can be performed flexographically to enable roll manufacturing.

One or more photovoltaic cells can include perovskite solar cells described above. The one or more perovskite cells can be coupled in parallel. The advantage of coupling the perovskite cells in parallel is that if a cell fails, the remaining, operating cells can continue to provide a voltage, a current, etc. The photovoltaic operation can produce an output voltage. In embodiments, the photovoltaic operation produces an output voltage in a range of 0.5V to 1.5V. The output voltage can depend on the material chosen for the perovskite layer. The perovskite solar cells can also produce an output current. In other embodiments, the photovoltaic operation produces an output current density greater than or equal to 20 mA/cm².

The system 700 can include an apparatus for solar energy generation comprising: a metallic foil substrate, wherein the metallic foil substrate is flexible and rollable; a transport layer on the metallic foil substrate, wherein the transport layer enables current conduction to the metallic foil substrate; a perovskite layer on the transport layer, wherein the perovskite layer generates an electric current based on light energy impingement; an additional transport layer on the perovskite layer, wherein the additional transport layer complements the transport layer; a conductive layer on the additional transport layer, wherein the conductive layer enables light transmission and isolates the additional transport layer; and a grid on the conductive layer, wherein the grid conducts electric current, wherein the grid enables light energy to reach the perovskite layer, and wherein the grid and the metallic foil substrate form contacts for photovoltaic operation.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for solar cell realization comprising:
obtaining a metallic foil substrate, wherein the metallic foil substrate is flexible and rollable;
depositing a transport layer on the metallic foil substrate, wherein the transport layer enables current conduction to the metallic foil substrate;
adding a perovskite layer onto the transport layer, wherein the perovskite layer generates an electric current based on light energy impingement;
providing an additional transport layer on the perovskite layer, wherein the additional transport layer complements the transport layer;
isolating the additional transport layer with a conductive layer, wherein the conductive layer enables light transmission; and
connecting a grid on the conductive layer, wherein the grid conducts electric current, wherein the grid enables light energy to reach the perovskite layer, and wherein the grid and the metallic foil substrate form contacts for photovoltaic operation.

2. The method of claim 1 wherein the transport layer comprises a hole transport layer (HTL).

3. The method of claim 2 wherein the HTL comprises a nickel oxide (NiOₓ) layer.

4. The method of claim 2 wherein the HTL comprises a poly[bis(4-phenyl)(2,4,6-trimethylphenyl)amine (PTAA) layer, a Copper(I) Oxide (Cu₂O) layer, a Copper(I) Thiocyanate (CuSCN) layer, a Copper Antimony Sulfide (CuSbS₂), a Poly(3-hexylthiophene) (P3HT) layer, a Poly(3,4-ethylenedioxythiophene) polystyrene sulfonate (PEDOT) layer, a Spiro-OMeTAD layer, a Copper(I) Iodide (CuI) layer, a Copper(I) Oxide (Cu₂O) layer, a Vanadium (V) Oxide (V₂O₅) layer, a Copper Bismuth Thiostannate (CBTS) layer, or a Copper Tin Sulfide (CFTS) layer.

5. The method of claim 4 wherein the PTAA layer is used in conjunction with a nickel oxide (NiOₓ) layer.

6. The method of claim 1 wherein the additional transport layer comprises an electron transport layer (ETL).

7. The method of claim 6 wherein the ETL comprises a tin(IV) oxide (SnO₂) layer.

8. The method of claim 6 wherein the ETL comprises a Co Fullerene layer, a Titanium Dioxide (TiO₂) layer, a [6,6]-Phenyl-C61-butyric acid methyl ester (PCBM) layer, a Zinc Oxide (ZnO) layer, an Indium Gallium Zinc Oxide (IGZO) layer, a Tungsten Disulfide (WS₂) layer, or a Cerium Oxide (CeO₂) layer.

9. The method of claim 1 wherein the photovoltaic operation produces an output voltage in a range of 0.5V to 1.5V.

10. The method of claim 1 wherein the photovoltaic operation produces an output current density greater than or equal to 20 mA/cm².

11. The method of claim 1 wherein a thin conducting layer is inserted between the metallic foil substrate and the transport layer.

12. The method of claim 11 wherein the thin conducting layer provides semiconductor stability for the transport layer.

13. The method of claim 1 wherein a stabilization layer is inserted between the transport layer and the perovskite layer.

14. The method of claim 13 wherein the stabilization layer comprises (1,3-bis(diphenylphosphino)-propane) (DPPP).

15. The method of claim 13 wherein the stabilization layer is inserted using a slot-coating process.

16. The method of claim 1 wherein a perovskite capping layer is inserted between the perovskite layer and the additional transport layer.

17. The method of claim 16 wherein the perovskite capping layer enables dangling bond passivation.

18. The method of claim 16 wherein the perovskite capping layer enables redox prevention.

19. The method of claim 16 wherein the perovskite capping layer enables a smoothed electric potential across the perovskite layer.

20. The method of claim 1 wherein the conductive layer comprises a conductive oxide.

21. The method of claim 1 wherein the conductive layer comprises a conductive polymer.

22. The method of claim 1 wherein the grid is formed on the conductive layer using screen printing.

23. The method of claim 22 wherein the screen printing is performed flexographically to enable roll manufacturing.

24. The method of claim 1 wherein the obtaining, the depositing, the adding, the providing, the isolating, and the connecting enable manufacture of a flexible perovskite solar cell.

25. The method of claim 24 wherein the flexible perovskite solar cell is produced in rolls.

26. The method of claim 1 wherein the metallic foil comprises gold, silver, copper, aluminum, nickel, titanium, stainless steel, Molybdenum, or a Molybdenum alloy.

27. An apparatus for solar energy generation comprising:
a metallic foil substrate, wherein the metallic foil substrate is flexible and rollable;
a transport layer on the metallic foil substrate, wherein the transport layer enables current conduction to the metallic foil substrate;
a perovskite layer onto the transport layer, wherein the perovskite layer generates an electric current based on light energy impingement;
an additional transport layer on the perovskite layer, wherein the additional transport layer complements the transport layer;
a conductive layer on the additional transport layer, wherein the conductive layer enables light transmission and isolates the additional transport layer; and
a grid on the conductive layer, wherein the grid conducts electric current, wherein the grid enables light energy to reach the perovskite layer, and wherein the grid and the metallic foil substrate form contacts for photovoltaic operation.

28. A computer system for solar cell realization comprising:
a memory which stores instructions;
one or more processors coupled to the memory wherein the one or more processors, when executing the instructions which are stored, are configured to:
obtain a metallic foil substrate, wherein the metallic foil substrate is flexible and rollable;
deposit a transport layer on the metallic foil substrate, wherein the transport layer enables current conduction to the metallic foil substrate;
add a perovskite layer onto the transport layer, wherein the perovskite layer generates an electric current based on light energy impingement;
provide an additional transport layer on the perovskite layer, wherein the additional transport layer complements the transport layer;
isolate the additional transport layer with a conductive layer, wherein the conductive layer enables light transmission; and
connect a grid on the conductive layer, wherein the grid conducts electric current, wherein the grid enables light energy to reach the perovskite layer, and wherein the grid and the metallic foil substrate form contacts for photovoltaic operation.
